(19) United States
(12) Patent Application Publication
(10) Pub. No.: US 2015/0294876 A1
(43) Pub. Date: Oct. 15, 2015

(54) METHODS OF FORMING SEMICONDUCTOR DEVICES, INCLUDING FORMING FIRST, SECOND, AND THIRD OXIDE LAYERS

(71) Applicant: Samsung Electronics Co., Ltd., Suwon-si (KR)

(72) Inventors: Sungsam Lee, Yongin-si (KR); Satoru Yamada, Seoul (KR); Min Hee Cho, Suwon-si (KR)

(21) Appl. No.: 14/593,236

(22) Filed: Jan. 9, 2015

(30) Foreign Application Priority Data
Apr. 10, 2014 (KR) 10-2014-0043151

(51) Int. Cl. H01L 21/28; H01L 21/3105; H01L 21/762

(52) U.S. Cl. CPC H01L 21/28282; H01L 21/76205; H01L 21/31051

(57) ABSTRACT

Methods of forming semiconductor devices are provided. A method of forming a semiconductor device includes forming a first oxide layer in a trench of a substrate, and forming a second oxide layer on the first oxide layer. Moreover, the method includes forming a third oxide layer on the second oxide layer.

### CROSS-REFERENCE TO RELATED APPLICATION

This U.S. non-provisional patent application claims priority under 35 U.S.C. §119 to Korean Patent Application No. 10-2014-0043151, filed on Apr. 10, 2014, in the Korean Intellectual Property Office, the disclosure of which is hereby incorporated herein by reference in its entirety.

### BACKGROUND

The present disclosure relates to methods of forming semiconductor devices. Semiconductor devices are becoming more highly integrated to provide high performance and low costs. Because the integration density of semiconductor devices may directly affect the costs of the semiconductor devices, highly integrated semiconductor devices may be increasingly demanded. As the integration density of the semiconductor devices increases, critical dimensions (CD) of gate electrodes are being reduced. Thus, an interference phenomenon between neighboring cells may occur by a coupling effect, thereby causing problems such as a soft program problem.

### SUMMARY

According to various embodiments of present inventive concepts, a method of fabricating a semiconductor device may include forming a trench in a substrate, forming a first oxide layer in the trench, forming a second oxide layer on the first oxide layer, forming a third oxide layer on the second oxide layer, and forming an insulating pattern on the third oxide layer such that the insulating pattern fills the trench. Moreover, a first density of the second oxide layer may be higher than a second density of the first oxide layer.

In various embodiments, the third oxide layer may be thicker than the first oxide layer, after forming the third oxide layer. In some embodiments, the second oxide layer may include the same material as the first and third oxide layers. In some embodiments, forming the second oxide layer may include performing a thermal oxidation process to increase a density of an upper portion of the first oxide layer. In some embodiments, a wet etch rate of the second oxide layer may be lower than respective wet etch rates of the first and third oxide layers. Moreover, forming the second oxide layer may include removing a dangling bond between the substrate and the first oxide layer.

According to various embodiments, the trench may include a first trench and a second trench, a first width of the first trench may be different from a second width of the second trench, and, after forming the third oxide layer, a thickness of the first oxide layer on a bottom surface of the first trench may be substantially equal to a thickness of the first oxide layer on a bottom surface of the second trench. In some embodiments, forming the second oxide layer may include forming the second oxide layer using a first temperature in a range of about 900° C. to about 1100° C., and forming the first oxide layer may include forming the first oxide layer using a second temperature lower than the first temperature.

In various embodiments, forming the first oxide layer may include conformally forming the first oxide layer on a bottom surface and a sidewall of the trench. In some embodiments, the first oxide layer may have a thickness in a range of about 30 Å to about 50 Å, after forming the third oxide layer. Moreover, the method of forming the semiconductor device may include planarizing the third oxide layer, the second oxide layer, and the first oxide layer to form a first oxide pattern, a second oxide pattern, and a third oxide pattern that are sequentially stacked, the first through third oxide patterns exposing at least a portion of the substrate outside of the trench; forming a gate insulating pattern on the portion of the substrate exposed by the first through third oxide patterns; and forming a gate electrode pattern on the gate insulating pattern.

A method of forming a semiconductor device, according to various embodiments, may include forming a first oxide layer in first and second trenches of a substrate, forming a second oxide layer on the first oxide layer in the first and second trenches, and forming a third oxide layer on the second oxide layer in the first and second trenches. A thickness of the first oxide layer may be substantially uniform in the first and second trenches, after forming the third oxide layer. Moreover, after forming the third oxide layer, the thickness of the first oxide layer may be a first thickness that is thinner than a second thickness of the third oxide layer.

In various embodiments, the first trench may include a first width that is narrower than a second width of the second trench, and forming the first oxide layer may include forming the first oxide layer in the second trench and in the first trench that includes the first width that is narrower than the second width of the second trench. Additionally or alternatively, after forming the third oxide layer, a ratio of the first thickness of the first oxide layer to the second thickness of the third oxide layer may be about 1:4. Moreover, after forming the third oxide layer, the first thickness of the first oxide layer may be in a range of about 30 Å to about 50 Å. In some embodiments, forming the second oxide layer may include performing a thermal oxidation process, after forming the first oxide layer, to increase a density of an upper portion of the first oxide layer.

A method of forming a semiconductor device, according to various embodiments, may include forming a first oxide layer in first and second trenches of a substrate, and forming a second oxide layer on the first oxide layer in the first and second trenches. Moreover, the method may include forming a third oxide layer on the second oxide layer in the first and second trenches, the first trench having a first width that is narrower than a second width of the second trench. A first thickness of the first oxide layer may be substantially uniform in the first and second trenches, after forming the third oxide layer, and the first thickness of the first oxide layer may be thinner than a second thickness of the third oxide layer, after forming the third oxide layer.

In various embodiments, after forming the third oxide layer, the second thickness of the third oxide layer may be thicker than a third thickness of the second oxide layer. Moreover, the method may include forming an insulating layer on the third oxide layer; planarizing the insulating layer, the third oxide layer, the second oxide layer, and the first oxide layer until a surface of the substrate outside of the first and second trenches is exposed; and forming a gate electrode pattern on the surface of the substrate after planarizing the insulating layer, the third oxide layer, the second oxide layer, and the first oxide layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIGS. 1 to 5 and 7 are cross-sectional views illustrating a method of fabricating a semiconductor device according to some embodiments of present inventive concepts;

FIG. 6A is a plan view illustrating an example of a device isolation pattern included in a semiconductor device according to some embodiments of present inventive concepts;

FIG. 6B is a plan view illustrating an example of a device isolation pattern included in a semiconductor device according to some embodiments of present inventive concepts;

FIGS. 8 to 12 are cross-sectional views illustrating a method of fabricating a semiconductor device according to some embodiments of present inventive concepts;

FIG. 13 is a graph illustrating a cumulative fail bit probability according to a data retention time of each of a comparison example and an experimental example;

FIG. 14 is a plan view illustrating an example of a semiconductor device including a device isolation pattern according to some embodiments of present inventive concepts;

FIG. 15 is a cross-sectional view taken along lines I-I′ and II-II′ of FIG. 14 to illustrate an example of a semiconductor device including a device isolation pattern according to some embodiments of present inventive concepts;

FIG. 16 is a perspective view illustrating an example of a semiconductor device including a device isolation pattern according to some embodiments of present inventive concepts;

FIG. 17 is a schematic block diagram illustrating an example of an electronic system including a semiconductor device according to some embodiments of present inventive concepts; and

FIG. 18 is a schematic block diagram illustrating an example of a memory card including a semiconductor device according to some embodiments of present inventive concepts.

### DETAILED DESCRIPTION

Example embodiments are described below with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout the description.

The terminology used herein is for the purpose of describing particular embodiments only and is not intended to be limiting of the embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein may be interpreted accordingly.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of example embodiments.

It will be understood that although the terms “first,” “second,” etc. may be used herein to describe various elements, these elements should not be limited by these terms. These terms are only used to distinguish one element from another. Thus, a “first” element could be termed a “second” element without departing from the teachings of the present embodiments.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

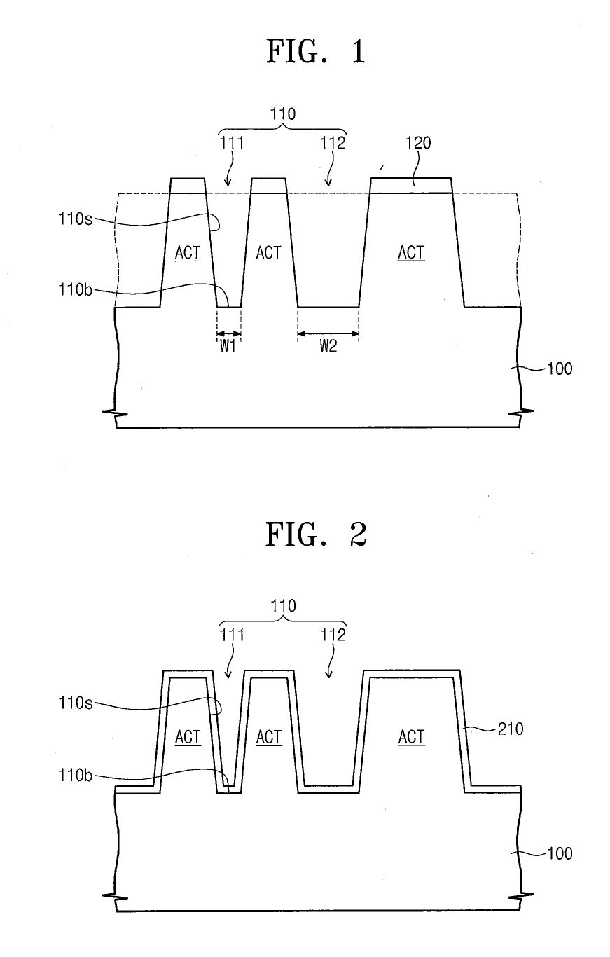

FIGS. 1 to 5 and 7 are cross-sectional views illustrating a method of fabricating a semiconductor device according to some embodiments of present inventive concepts.

Referring to FIG. 1, a substrate 100 having trenches 110 may be provided. The substrate 100 may be formed of a semiconductor material. For example, the substrate 100 may be a silicon substrate, a germanium substrate, or a silicon-germanium substrate. A mask pattern 120 may be formed on the substrate 100. The substrate 100 may be etched using the mask pattern 120 as an etch mask to form the trenches 110. Bottom surfaces 110b and sidewalls 110s of the trenches 110 may be damaged by the etching process used for the formation of the trenches 110. For example, dangling bonds may be generated on the bottom surfaces 110b and sidewalls 110s of the trenches 110. An active region ACT may be defined between adjacent ones of the trenches 110. The active region ACT may be a portion of the substrate 100 surrounded by the trenches 110. The trenches 110 may include a first trench 111 and a second trench 112. The first trench 111 and the second trench 112 may have widths different from each other. For example, the first trench 111 may have a first width W1, and the second trench 112 may have a second width W2 greater than the first width W1. Here, the widths W1 and W2 of the first and second trenches 111 and 112 may be defined as widths of the bottom surfaces 110b of the first and second trenches 111 and 112, respectively. The mask pattern 120 may be removed after the formation of the trenches 110.

Referring to FIG. 2, a first oxide layer 210 may be formed on the substrate 100. The first oxide layer 210 may include an insulating oxide such as silicon oxide. The first oxide layer 210 may be formed by an atomic layer deposition method. Thus, the first oxide layer 210 may conformally cover the bottom surface 110b and the sidewall(s) 110s of each of the trenches 110. For example, a thickness of the first oxide layer 210 disposed on the bottom surface 110b of the trench 110 may be substantially equal or similar to a thickness of the first oxide layer 210 disposed on the sidewall(s) 110s of the trench 110. The thickness of the first oxide layer 210 may be in a range of 30 Å to 50 Å. If the first oxide layer 210 has a non-uniform thickness or a relatively large thickness (e.g., a thickness greater than 50 Å), a defect such as a void or a seam may be formed in the first oxide layer 210 formed in the trench 110 having a narrow width during the process of depositing the first oxide layer 210. According to some embodiments, the first oxide layer 210 may have a uniform and relatively thin thickness, and thus, the defect (e.g., the void or seam) may not be formed in the first oxide layer 210 in the trench having a narrow width (e.g., the first trench 111). The first oxide layer 210 may function as a liner layer.

A process temperature of the formation process of the first oxide layer 210 may be in a range of about 550° C. to about 700° C. If the first oxide layer 210 is formed at a temperature higher than 700° C., a surface of the active region ACT may be damaged. Thus, a width of the active region ACT may be excessively reduced. According to some embodiments, since the first oxide layer 210 is formed at the proper temperature in the range of about 550° C. to about 700° C., the first oxide layer 210 may not be excessively reduced.

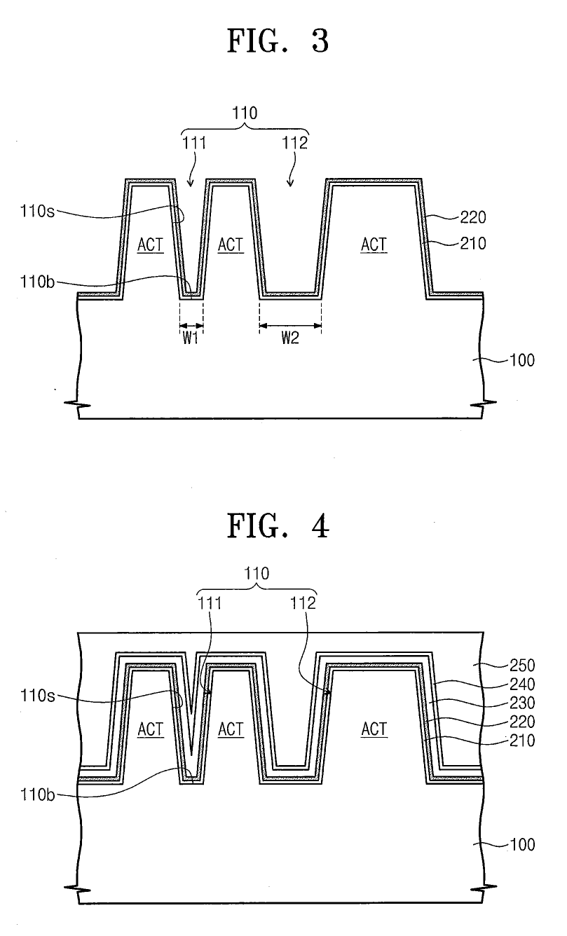

Referring to FIG. 3, a second oxide layer 220 may be formed on the first oxide layer 210. The second oxide layer 220 may be provided on the bottom surface 110b and the sidewall(s) 110s of each of the trenches 110. The second oxide layer 220 may be formed by performing a thermal oxidation process on the first oxide layer 210. In some embodiments, an upper portion of the first oxide layer 210 may become denser by the thermal oxidation process to form the second oxide layer 220. The second oxide layer 220 may include the same material as the first oxide layer 210. For example, the second oxide layer 220 may include silicon oxide. A density of the second oxide layer 220 may be higher than a density of the first oxide layer 210. An atomic ratio of oxygen in the silicon oxide of the second oxide layer 220 may be different from an atomic ratio of oxygen in the silicon oxide of the first oxide layer 210. An etch rate of the second oxide layer 220 may be different from an etch rate of the first oxide layer 210. For example, the etch rate of the second oxide layer 220 may be lower than that of the first oxide layer 210 during a wet etching process using hydrofluoric acid. In some embodiments, the second oxide layer 220 may be deposited on the first oxide layer 210 by a thermal oxidation process.

The second oxide layer 220 may be a liner layer. Gases such as an oxygen source gas may be used during the formation process of the second oxide layer 220. The gases may penetrate the first oxide layer 210 to reach the sidewalls 110s and the bottom surfaces 110b of the trenches 110. The gases may react with the dangling bonds formed on the sidewalls 110s and the bottom surfaces 110b of the trenches 110, and thus, the dangling bonds may be reduced/cured. As a result, an interface trap characteristic between active region ACT and the first oxide layer 210 may be improved.

The thickness and the structure of the first oxide layer 210 may affect the number of the dangling bonds removed during the formation process of the second oxide layer 220. For example, since the first oxide layer 210 has the small thickness (e.g., a thickness of 50 Å or less), the gases may penetrate the first oxide layer 210. However, if the first oxide layer 210 has too small of a thickness (e.g., a thickness smaller than 30 Å), the gases may remove the dangling bonds and may also react with the active region ACT and the substrate 100 adjacent to the bottom surface 110b of the trench 110. Thus, the active region ACT may be damaged to reduce the width of the active region ACT. If the first oxide layer 210 has a non-uniform thickness, the dangling bonds formed on inner surfaces of the trenches 110 may not be sufficiently removed, or the width of the active region ACT may be reduced. For example, if the first oxide layer 210 disposed on the bottom surface 110b of the first trench 111 is thicker than the first oxide layer 210 disposed on the sidewall(s) 110s of the first trench 111, the dangling bonds of the sidewall(s) 110s may be reduced/cured but the dangling bonds of the bottom surface 110b may be difficult to reduce/cure. Alternatively, the dangling bonds of the bottom surface 110b of the first trench 111 may be removed but the sidewall(s) 110s of the first trench 111 may be damaged by the gases. According to some embodiments, since the first oxide layer 210 in the first trench 111 has the uniform thickness, the dangling bonds of the sidewall(s) 110s and the bottom surface 110b of the first trench 111 may be removed without reduction of the thickness of the active region ACT. The thickness of the first oxide layer 210 disposed on the bottom surface 110b of the first trench 111 may be substantially equal to the thickness of the first oxide layer 210 disposed on the bottom surface 110b of the second trench 112. Thus, the dangling bonds formed on inner surfaces of the first and second trenches 111 and 112 may be reduced/cured regardless of the widths W1 and W2 of the first and second trenches 111 and 112.

A process temperature of the formation process of the second oxide layer 220 may be higher than that of the formation process of the first oxide layer 210. For example, the process temperature of the second oxide layer 220 may be in a range of about 900° C. to about 1100° C. If the process temperature of the second oxide layer 220 is lower than 900° C., the dangling bonds between the first oxide layer 210 and the sidewall(s) 110s of the trench 110 may not be sufficiently removed. In some embodiments, the second oxide layer 220 may be formed by a radical oxidation process.

Referring to FIG. 4, a third oxide layer 230 and a nitride layer 240 may be sequentially formed on the second oxide layer 220. The third oxide layer 230 may include the same material (e.g., silicon oxide) as the first and second oxide layers 210 and 220. However, an atomic ratio of oxygen in the silicon oxide of the third oxide layer 230 may be different from an atomic ratio of the oxygen in the silicon oxide of the second oxide layer 220. The third oxide layer 230 may be formed by an atomic layer deposition method. Here, a process condition of the atomic layer deposition method used for the formation of the third oxide layer 230 may be the same as that of the atomic layer deposition method used for the formation of the first oxide layer 210. For example, the third oxide layer 230 may be formed at a process temperature in a range of about 550° C. to about 700° C. The second oxide layer 220 may be denser than the third oxide layer 230. In other words, the second oxide layer 220 may include the same material as the third oxide layer 230 but the density of the second oxide layer 220 may be higher than that of the third oxide layer 230. An etch rate of the third oxide layer 230 may be different from that of the second oxide layer 220. For example, the etch rate of the third oxide layer 230 may be higher than that of the second oxide layer 220 in a wet etching process using hydrofluoric acid. Interface traps between the substrate 100 and the first oxide layer 210 may be further reduced by the third oxide layer 230. In some embodiments, a ratio of the thickness of the first oxide layer 210 to a thickness of the third oxide layer 230 may be about 2:8 (i.e., 1:4). A sum of the thicknesses of the first, second and third oxide layers 210, 220 and 230 may be uniform. Due to the third oxide layer 230, the first oxide layer 210 may have the thickness in the range of 30 Å to 50 Å. Interface traps (i.e., the dangling bonds) between the first oxide layer 210 and the active region ACT may be reduced as a ratio of the thickness of the second oxide layer 220 to the sum of the thicknesses of the first to third oxide layers 210, 220, and 230 increases. The third oxide layer 230 may act as a liner layer.

The nitride layer 240 may be formed on the third oxide layer 230. The nitride layer 240 may be provided on the bottom surfaces 110b and the sidewalls 110s of the trenches 110. The nitride layer 240 may include silicon nitride. The nitride layer 240 may act as a liner layer.

An insulating layer 250 may be formed on the substrate 100. The insulating layer 250 may be disposed on the nitride layer 240 to fill the trenches 110. In some embodiments, the insulating layer 250 may include silazane (e.g., “tonen silazene (TOSZ)”).

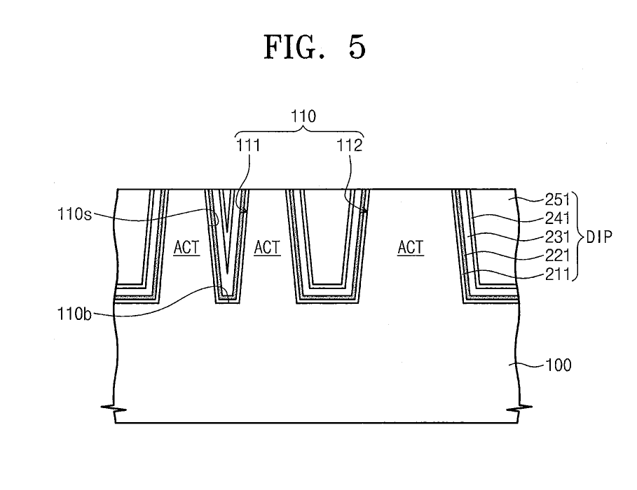

Referring to FIG. 5, a device isolation pattern DIP may be formed in each of the trenches 110 to define the active region ACT. The device isolation pattern DIP may include a first oxide pattern 211, a second oxide pattern 221, a third oxide pattern 231, a nitride pattern 241, and an insulating pattern 251. For example, the insulating layer 250, the nitride layer 240, and the oxide layers 230, 220, and 210 may be planarized until a top surface of the active region ACT is reached/exposed. Thus, the insulating layer 250, the nitride layer 240, and the oxide layers 230, 220, and 210 disposed on the top surface of the active region ACT may be removed to form the first oxide pattern 211, the second oxide pattern 221, the third oxide pattern 231, the nitride pattern 241, and the insulating pattern 251 in each of the trenches 110. As a result, the device isolation pattern DIP according to some embodiments may be completed.

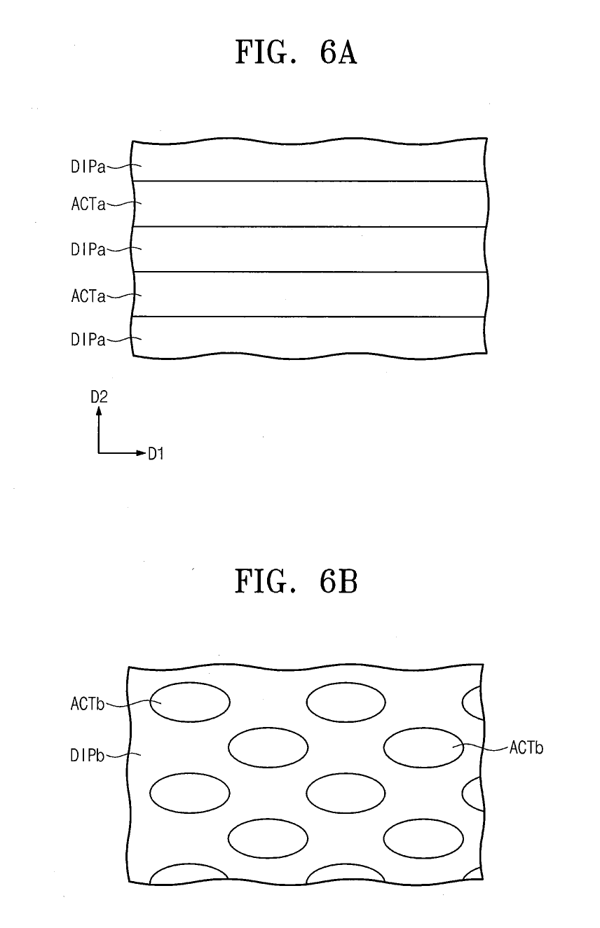

The device isolation pattern DIP may have one of various shapes when viewed from a plan view. This is described further with reference to FIGS. 6A and 6B.

FIG. 6A is a plan view illustrating an example of a device isolation pattern included in a semiconductor device according to some embodiments of present inventive concepts.

Referring to FIG. 6A, a device isolation pattern DIPa may extend in a first direction D1. The device isolation pattern DIPa may be the device isolation pattern DIP described with reference to FIG. 5. The device isolation pattern DIPa may be provided in plurality. The plurality of device isolation patterns DIPa may be spaced apart from each other and may extend parallel to each other in the first direction D1.

An active region ACTa may be defined between adjacent/parallel ones of the device isolation patterns DIPa. The active region ACTa may be the active region ACT described with reference to FIG. 5. A plurality of active regions ACTa may be spaced apart from each other when viewed from a plan view. The plurality of active regions ACTa may extend in the first direction D1.

FIG. 6B is a plan view illustrating an example of a device isolation pattern included in a semiconductor device according to some embodiments of present inventive concepts.

Referring to FIG. 6B, a plurality of active regions ACTb may be defined by a device isolation pattern DIPb. When viewed from a plan view, the plurality of active regions ACTb may be spaced apart from each other. Each of the active regions ACTb may have an island shape. The active regions ACTb may correspond to portions of the substrate 100 surrounded by the device isolation pattern DIPb. The device isolation pattern DIPb and the active region ACTb may be the device isolation pattern DIP and the active region ACT of FIG. 5, respectively.

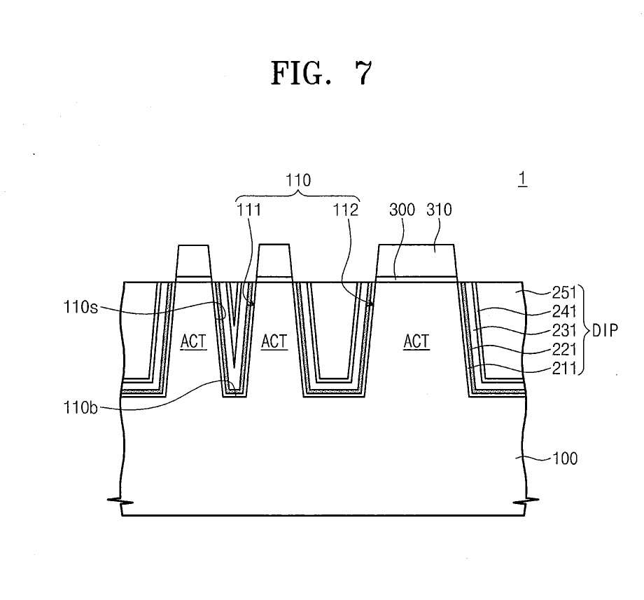

Referring to FIG. 7, a gate insulating pattern 300 and a gate electrode pattern 310 may be sequentially formed on the active region ACT. In some embodiments, the gate insulating pattern 300 may include at least one of silicon oxide, silicon nitride, silicon carbide, silicon oxynitride, or silicon carbonitride. In some embodiments, the gate insulating pattern 300 may include a high-k dielectric material such as hafnium oxide. The gate electrode pattern 310 may be disposed on the gate insulating pattern 300. In some embodiments, the gate electrode pattern 310 may be a memory element. For example, the gate electrode pattern 310 may be a medium that stores a single-bit or a multi-bit by a charge storing method, a resistance varying method, or another method. In some embodiments, the gate electrode pattern 310 may be a peripheral circuit element. As a result, a semiconductor device 1 may be fabricated/formed.

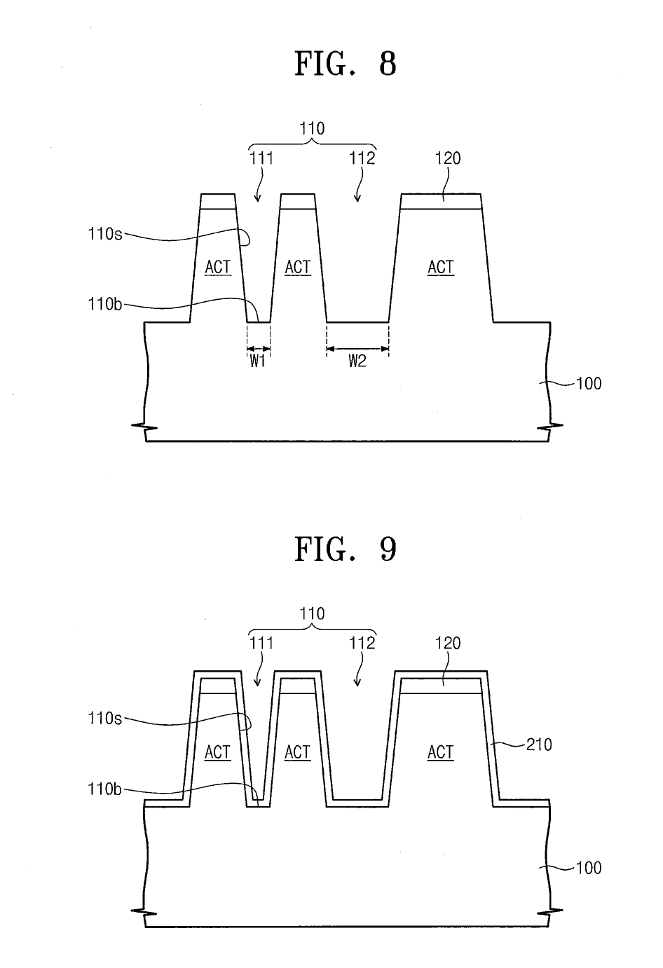

FIGS. 8 to 12 are cross-sectional views illustrating a method of fabricating a semiconductor device according to some embodiments of present inventive concepts. Repeated descriptions with respect to FIGS. 1-7 may be omitted or mentioned briefly for the purpose of ease and convenience in explanation.

Referring to FIG. 8, a substrate 100 having trenches 110 may be provided. In some embodiments, the substrate 100 may be etched using a mask pattern 120 as an etch mask to form the trenches 110. The trenches 110 may include a first trench 111 and a second trench 112. A width W1 of the first trench 111 may be different from a width W2 of the second trench 112. An active region ACT may be defined between adjacent ones of the trenches 110. In some embodiments, the mask pattern 120 may remain rather than being removed.

Referring to FIG. 9, a first oxide layer 210 may be formed on the substrate 100. The first oxide layer 210 may include an insulating oxide such as silicon oxide. The first oxide layer 210 may be formed at a process temperature of about 550° C. to about 700° C. by an atomic layer deposition method. Thus, the first oxide layer 210 may conformally cover a bottom surface 110b and sidewall(s) 110s of each of the trenches 110 and a top surface of the mask pattern 120. The first oxide layer 210 may have a thickness of 30 Å to 50 Å. According to some embodiments, a void or a seam may not be formed in the first oxide layer 210 which is formed in a narrow trench such as the first trench 111.

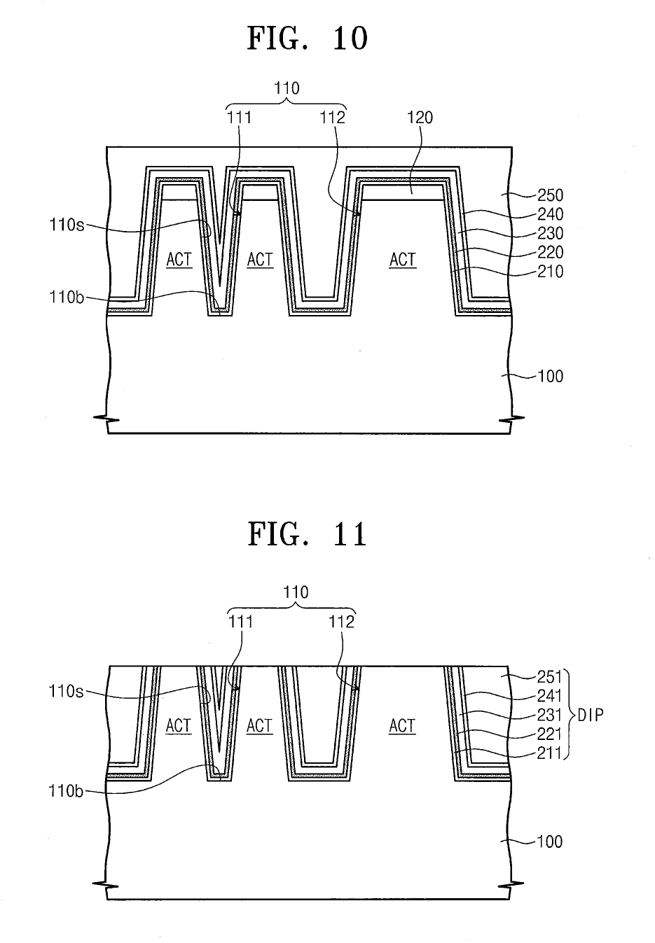

Referring to FIG. 10, a second oxide layer 220 may be formed on the first oxide layer 210. The second oxide layer 220 may be provided on the bottom surface 110b and the sidewall(s) 110s of each of the trenches 110. In some embodiments, the second oxide layer 220 may be formed by performing a thermal oxidation process on the first oxide layer 210. An upper portion of the first oxide layer 210 may become denser by the thermal oxidation process to form the second oxide layer 220. In some embodiments, the second oxide layer 220 may be deposited on the first oxide layer 210 by the thermal oxidation process. The second oxide layer 220 may include the same material (e.g., silicon oxide) as the first oxide layer 210. At this time, a density of the second oxide layer 220 may be higher than a density of the first oxide layer 210. A wet etch rate of the second oxide layer 220 may be lower than a wet etch rate of the first oxide layer 210. A process temperature of the formation process of the second oxide layer 220 may be higher than that of the formation process of the first oxide layer 210. For example, the process temperature of the second oxide layer 220 may be in a range of about 900° C. to about 1100° C.

Dangling bonds formed on the sidewalls 110s and the bottom surfaces 110b of the trenches 110 may be reduced/cured by an oxygen source gas during the formation process of the second oxide layer 220, thereby improving an interface trap characteristic between the active region ACT and the first oxide layer 210. The interface trap characteristic may be controlled by controlling the thickness of the first oxide layer 210 and/or conditions of the thermal oxidation process.

A third oxide layer 230 and a nitride layer 240 may be sequentially formed on the second oxide layer 220. The third oxide layer 230 may include the same material (e.g., silicon oxide) as the first oxide layer 210. The third oxide layer 230 may be formed at a process temperature ranging from about 550° C. to about 700° C. by an atomic layer deposition method. The second oxide layer 220 may be denser than the third oxide layer 230. The wet etch rate of the second oxide layer 220 may be lower than a wet etch rate of the third oxide layer 230. For example, the second oxide layer 220 may include the same material as the third oxide layer 230 but an atomic ratio of the second oxide layer 220 may be different from an atomic ratio of the third oxide layer 230. The third oxide layer 230 may be thicker than the first oxide layer 210. Interface traps (i.e., the dangling bonds) between the first oxide layer 210 and the active region ACT may be reduced as a ratio of the thickness of the second oxide layer 220 to a sum of the thicknesses of the first to third oxide layers 210, 220, and 230 increases.

The nitride layer 240 may be formed on the third oxide layer 230. The nitride layer 240 may be provided on the bottom surface 110b and the sidewall(s) 110s of each of the trenches 110. The nitride layer 240 may include silicon nitride. An insulating layer 250 may be formed on the nitride layer 240 to fill the trenches 110.

Referring to FIG. 11, a first oxide pattern 211, a second oxide pattern 221, a third oxide pattern 231, a nitride pattern 241, and an insulating pattern 251 may be formed in each of the trenches 110. For example, a planarization process may be performed to remove the mask pattern 120, the insulating layer 250, the nitride layer 240, and the oxide layers 230, 220 and 210 disposed on the top surface of the active region ACT. Thus, the top surface of the active region ACT may be exposed. As a result, the device isolation pattern DIP according to some embodiments may be fabricated/formed.

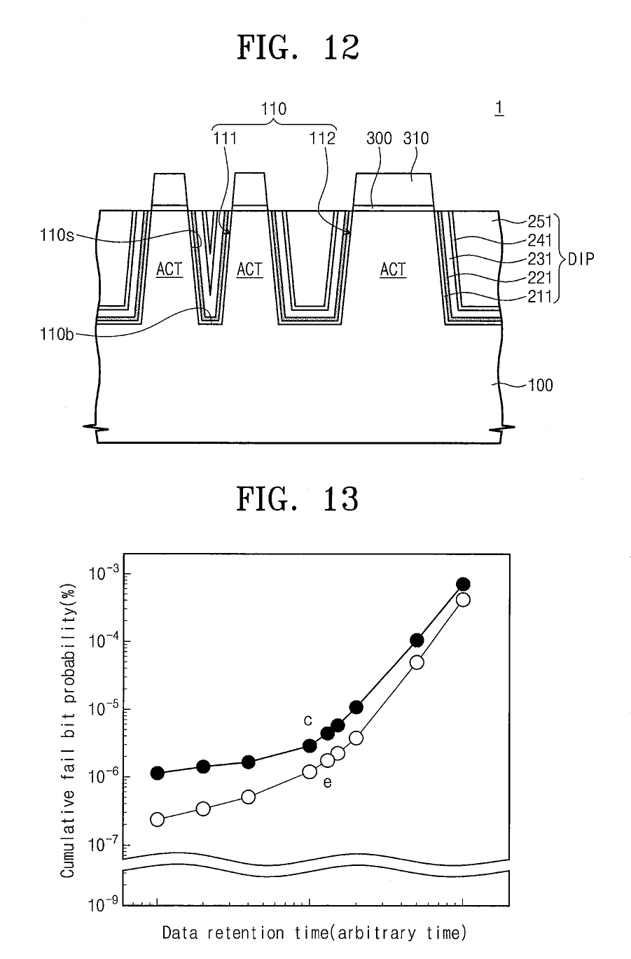

Referring to FIG. 12, a gate insulating pattern 300 and a gate electrode pattern 310 may be sequentially formed on the active region ACT. In other words, the gate electrode pattern 310 may be disposed on the gate insulating pattern 300. The gate electrode pattern 310 may be a memory element or a peripheral circuit element. As a result, the semiconductor device 1 may be fabricated.

FIG. 13 is a graph illustrating a cumulative fail bit probability according to a data retention time of each of a comparison example and an experimental example. A cumulative fail bit probability according to a data retention time was evaluated for each of a comparison example and an experimental example. The semiconductor device 1 of the experimental example e included the device isolation pattern DIP having the first to third oxide patterns 211, 221 and 231, the nitride pattern 241, and the insulating pattern 251, as illustrated in FIG. 12. A device isolation pattern of a semiconductor device of the comparison example c did not include the third oxide pattern 231 and included a first oxide pattern thicker than the first oxide pattern 211 illustrated in FIG. 12. Other elements of the device isolation pattern of the comparison example c were the same as corresponding ones of the device isolation pattern DIP of the experimental example e, respectively. Hereinafter, repeated descriptions with respect to FIGS. 1-12 may be omitted or mentioned briefly for the purpose of ease and convenience in explanation.

Referring to FIGS. 12 and 13, the cumulative fail bit probability of the experimental example e is lower than that of the comparison example c at the same data retention time. Since the experimental example e includes the third oxide layer 230, the first oxide layer 210 of the experimental example e can be thinner than the first oxide layer of the comparison example c and can be uniform (e.g., can have a uniform thickness), in contrast with the first oxide layer of the comparison example c. Thus, the number of interface traps between the substrate 100 and the oxide patterns 211, 221 and 231 of the experimental example e may be smaller than the number of interface traps between a substrate and oxide patterns of the comparison example c. As a result, a gate induced drain leakage (GIDL) of the experimental example e may be lower than that of the comparison example c, thereby improving performance of the semiconductor device 1 of the experimental example e.

A semiconductor device including the device isolation pattern fabricated according to some embodiments described with respect to any of FIGS. 1-12 may be provided. The semiconductor device may include at least one of a highly integrated semiconductor memory device (e.g., a dynamic random access memory (DRAM) device, a static random access memory (SRAM) device, a phase change random access memory (PRAM) device, a resistance random access memory (RRAM) device, a magnetic random access memory (MRAM) device, and/or a ferroelectric random access memory (FRAM) device), a complementary metal-oxide-semiconductor (CMOS) image sensor (CIS), a micro electro mechanical system (MEMS), an optoelectronic device, a central processing unit (CPU), or a digital signal processor (DSP). In addition, the semiconductor device may include the same kind of semiconductor devices or a single-chip data processing device such as a system-on-chip (SOC) that consists of different kinds of semiconductor devices required for providing one complete function.

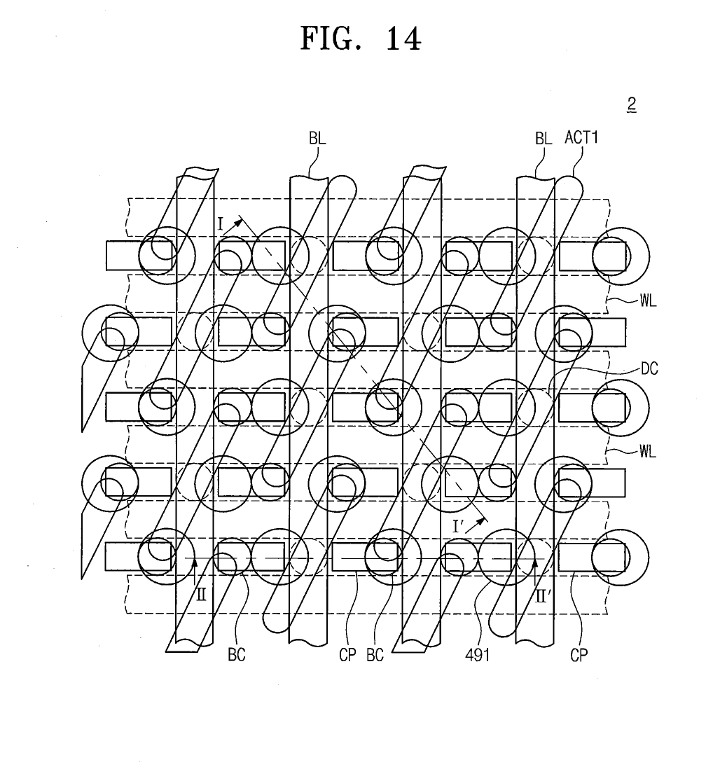

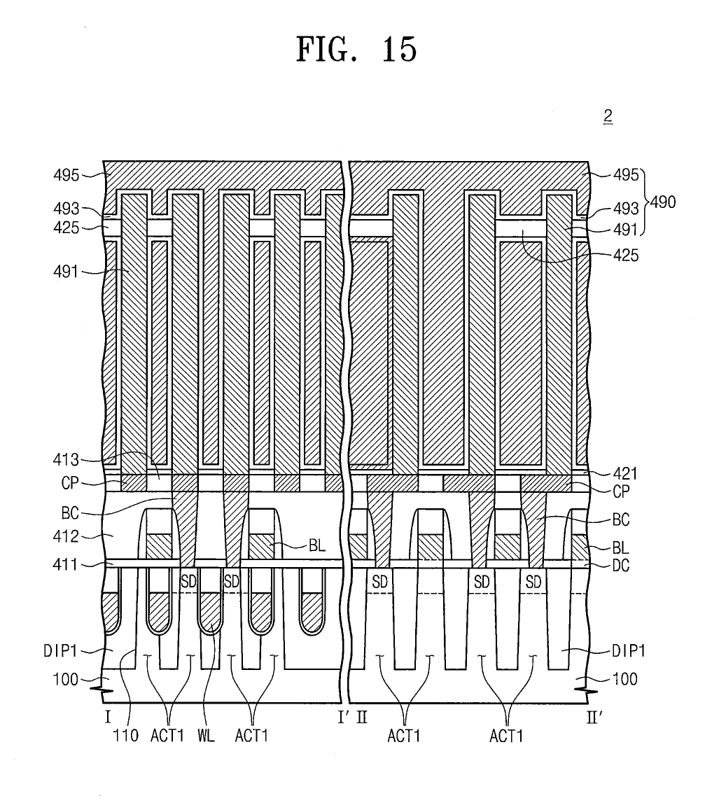

A semiconductor memory device including the device isolation pattern according to some embodiments of present inventive concepts is described herein with reference to FIGS. 14 and 15. FIG. 14 is a plan view illustrating an example of a semiconductor device including a device isolation pattern according to some embodiments of present inventive concepts. FIG. 15 is a cross-sectional view taken along lines I-I′ and II-II′ of FIG. 14 to illustrate an example of a semiconductor device including a device isolation pattern according to some embodiments of present inventive concepts.

Referring to FIGS. 14 and 15, a semiconductor device 2 includes word lines WL, bit lines BL intersecting the word lines WL, and memory cells respectively disposed at intersecting points of the word lines WL and bit lines BL. The bit lines BL may be perpendicular to the word lines WL.

In more detail, a device isolation pattern DIP1 is provided in a substrate 100 to define active regions ACT1. The device isolation pattern DIP1 may be formed as described with reference to FIGS. 1 to 5 or 8 to 11. For example, the device isolation pattern DIP1 may be provided in each of the trenches 110 of the substrate 100 and may include the first oxide pattern 211, the second oxide pattern 221, the third oxide pattern 231, the nitride pattern 241, and the insulating pattern 251, which are sequentially stacked, as illustrated in FIG. 5 or 11. Thus, interface traps between the active region ACT1 and the device isolation pattern DIP1 may be reduced. When viewed from a plan view, the active region ACT1 and the device isolation pattern DIP1 may have the shapes described with reference to FIG. 6B. The active region ACT1 may have a bar shape extending in one direction when viewed from a plan view. A long axis of the active region ACT1 may be in a diagonal direction with respect to the word lines WL and the bit lines BL.

The word lines WL may intersect the active regions ACT1. In some embodiments, the word lines WL may be disposed in recess regions that are recessed by a predetermined depth from a top surface of the substrate 100. A gate insulating layer may be disposed between each of the word lines WL and an inner surface of each of the recess regions. In addition, a top surface of a word line WL may be lower than the top surface of the substrate 100, and an insulating material may be disposed on the word line WL to fill the recess region.

Source/drain regions SD may be formed in the active region ACT1 at both sides of each of the word lines WL. The source/drain regions SD may be dopant regions doped with dopants.

A plurality of metal-oxide-semiconductor (MOS) transistors may be realized by the word lines WL and the source/drain regions SD described herein.

The bit lines BL may be disposed on the substrate 100 to cross over the word lines WL. A first interlayer insulating layer 411 may be disposed between the substrate 100 and the bit lines BL. Bit line contact plugs DC may be formed in the first interlayer insulating layer 411 to electrically connect the bit lines BL to some of the source/drain regions SD.

A second interlayer insulating layer 412 may cover the bit lines BL. Contact plugs BC may be formed in the second interlayer insulating layer 412 to electrically connect ones of the source/drain regions SD to data storage elements. In some embodiments, the contact plugs BC may be disposed on the active region ACT1 at both sides of the bit line BL.

A forming process of the contact plugs BC may include forming contact holes exposing ones of the source/drain regions SD in the second interlayer insulating layer 412, depositing a conductive layer filling the contact holes, and planarizing the conductive layer. The contact plugs BC may be formed of at least one of a poly-silicon layer doped with dopants, a metal layer, a metal nitride layer, or a metal silicide layer.

In some embodiments, contact pads CP may be formed on respective ones of the contact plugs BC. The contact pads CP may be two-dimensionally arranged on the second interlayer insulating layer 412. A contact pad CP may increase a contact area between a contact plug BC and a lower electrode of a capacitor formed on the contact pad CP. For example, two contact pads CP that are adjacent to each other with the bit line BL therebetween in a plan view may extend in opposite directions to each other.

An etch stop layer 421 may be formed on a third interlayer insulating layer 413, in which the contact pads CP are provided. A thickness of the etch stop layer 421 may be changed depending on a thickness of lower electrodes 491 of a cylindrical capacitor or a desired capacitance of the capacitor.

The lower electrodes 491 may be disposed on respective ones of the contact pads CP. The lower electrodes 491 may be electrically connected to respective ones of the contact pads CP. Each of the lower electrodes 491 may have a pillar shape or a cylindrical shape. The lower electrodes 491 may be arranged in a zigzag form or a honeycomb form. A dielectric layer 493 may be provided to conformally cover surfaces of the lower electrodes 491, and an upper electrode 495 may be formed on the dielectric layer 493. The lower electrode 491, the upper electrode 495, and the dielectric layer 493 therebetween may constitute a capacitor 490. In some embodiments, a supporting pattern 425 may be disposed between upper portions of the lower electrodes 491. In this case, the dielectric layer 493 may also cover a surface of the supporting pattern 425. The supporting pattern 425 may have an opening penetrated by a lower electrode 491.

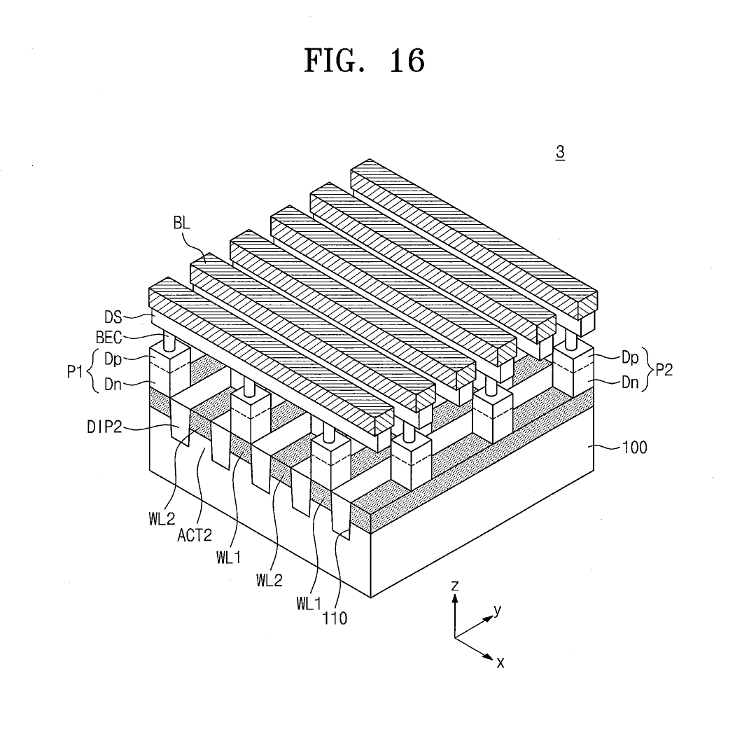

FIG. 16 is a perspective view illustrating a variable resistance memory device including a device isolation pattern according to some embodiments of present inventive concepts.

Referring to FIG. 16, a substrate 100 including a device isolation pattern DIP2 and an active region ACT2 may be provided. The device isolation pattern DIP2 may be fabricated as described with reference to FIGS. 1, to 5 or 8 to 11. For example, the device isolation pattern DIP2 may be provided in each of the trenches 110 of the substrate 100 and may include the first oxide pattern 211, the second oxide pattern 221, the third oxide pattern 231, the nitride pattern 241, and the insulating pattern 251 which are sequentially stacked, as illustrated in FIG. 5 or 11. Thus, interface traps between the active region ACT2 and the device isolation pattern DIP2 may be reduced. The active region ACT2 and the device isolation pattern DIP2 may have the shapes described with reference to FIG. 6A when viewed from a plan view.

A semiconductor device 3 may include the substrate 100, lower interconnections (e.g., word lines) WL1 and WL2 disposed in the substrate 100, upper interconnections BL intersecting the lower interconnections WL1 and WL2, selection elements respectively disposed at intersecting points of the upper interconnections (e.g., bit lines) BL and the lower interconnections WL1 and WL2, and memory elements DS disposed between the selection elements and the upper interconnections BL. The selection elements may be two-dimensionally arranged on the substrate 100. A selection element may control a current flow penetrating a memory element.

In more detail, each of the lower interconnections WL1 and WL2 may have a linear shape extending in a y-axis direction in each of the active regions ACT2. In some embodiments, the lower interconnections WL1 and WL2 may be dopant regions that are formed by heavily doping the active regions ACT2 with dopants. Here, a conductivity type of the lower interconnections WL1 and WL2 may be opposite to that of the substrate 100.

The selection elements may include semiconductor patterns P1 and P2. Each of first and second semiconductor patterns P1 and P2 may include an upper dopant region Dp and a lower dopant region Dn. A conductivity type of the upper dopant region Dp may be opposite to a conductivity type of the lower dopant region Dn. For example, the lower dopant region Dn may have the same conductivity type as the lower interconnections WL1 and WL2, and the upper dopant region Dp may have the conductivity type opposite to the conductivity type of the lower interconnections WL1 and WL2. Thus, a PN junction may be generated in each of the first and second semiconductor patterns P1 and P2. Alternatively, an intrinsic region may be disposed between the upper dopant region Dp and the lower dopant region Dn, so a PIN junction may be generated in each of the first and second semiconductor patterns P1 and P2. Meanwhile, a PNP or NPN bipolar transistor may be realized by the substrate 100, the lower interconnection WL1 or WL2, and the first or second semiconductor pattern P1 or P2.

Lower electrodes BEC, the memory elements DS, and the upper interconnections BL may be disposed on the first and second semiconductor patterns P1 and P2. The upper interconnections BL may cross over the lower interconnections WL1 and WL2 and may be disposed on the memory elements DS. The upper interconnections BL may be electrically connected to the memory elements DS.

According to some embodiments, each of the memory elements DS may be formed to be parallel to the upper interconnections BL and may be connected to a plurality of lower electrodes BEC. Alternatively, the memory elements DS may be two-dimensionally arranged. In other words, the memory elements DS may be disposed on the first and second semiconductor patterns P1 and P2 in one-to-one correspondence. A memory element DS may be a variable resistance pattern that is switchable between two resistance states by an electrical pulse applied to the memory element DS. In some embodiments, the memory element DS may include a phase-change material of which a phase is changeable between a crystalline state and an amorphous state according to an amount of current. In some embodiments, a memory element DS may include at least one of a perovskite compound, a transition metal oxide, a magnetic material, a ferromagnetic material, or an antiferromagnetic material.

Each of the lower electrodes BEC may be disposed between each of the first and second semiconductor patterns P1 and P2 and one of the memory elements DS. A planar area of the lower electrode BEC may be smaller than a planar area of each of the first and second semiconductor patterns P1 and P2 and/or a planar area of the memory element DS.

In some embodiments, the lower electrode BEC may have a pillar shape. Alternatively, the shape of the lower electrode BEC may be variously modified to reduce its cross-sectional area. For example, the lower electrode BEC may have a three-dimensional structure such as a U-shaped structure, an L-shaped structure, a hollow cylindrical shape, a ring structure, or a cup structure.

In addition, an ohmic layer for reducing a contact resistance may be disposed between each of the lower electrodes BEC and each of the first and second semiconductor patterns P1 and P2. For example, the ohmic layer may include a metal silicide layer such as titanium silicide, cobalt silicide, tantalum silicide, or tungsten silicide.

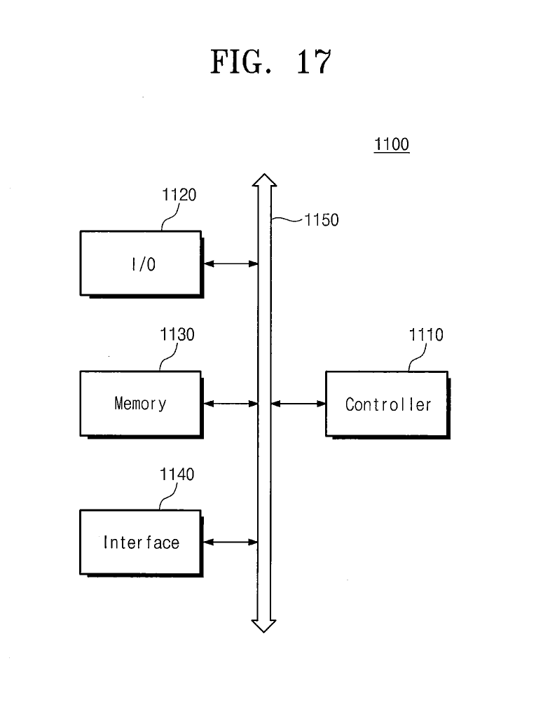

FIG. 17 is a schematic block diagram illustrating an example of an electronic system including a semiconductor device according to some embodiments of present inventive concepts.

Referring to FIG. 17, an electronic system 1100 according to some embodiments of present inventive concepts may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may correspond to a path through which electrical signals are transmitted.

The controller 1110 may include at least one of a microprocessor, a digital signal processor, a microcontroller, or other logic devices. The other logic devices may have a similar function to any one of the microprocessor, the digital signal processor and the microcontroller. The I/O unit 1120 may include a keypad, a keyboard and/or a display device. The memory device 1130 may store data and/or commands. The memory device 1130 may include at least one of the semiconductor devices described herein with respect to FIGS. 1-16. The interface unit 1140 may transmit electrical data to a communication network or may receive electrical data from a communication network. The interface unit 1140 may operate wirelessly or by cable. For example, the interface unit 1140 may include an antenna or a wireless/cable transceiver. The electronic system 1100 may further include a fast DRAM device and/or a fast SRAM device which acts as a cache memory for improving an operation of the controller 1110. The fast DRAM device and/or the fast SRAM device may include a device isolation pattern according to embodiments described herein with respect to FIGS. 1-16.

The electronic system 1100 may be applied to a personal digital assistant (PDA), a portable computer, a web tablet, a wireless phone, a mobile phone, a digital music player, a memory card or other electronic products. The other electronic products may receive or transmit information data wirelessly.

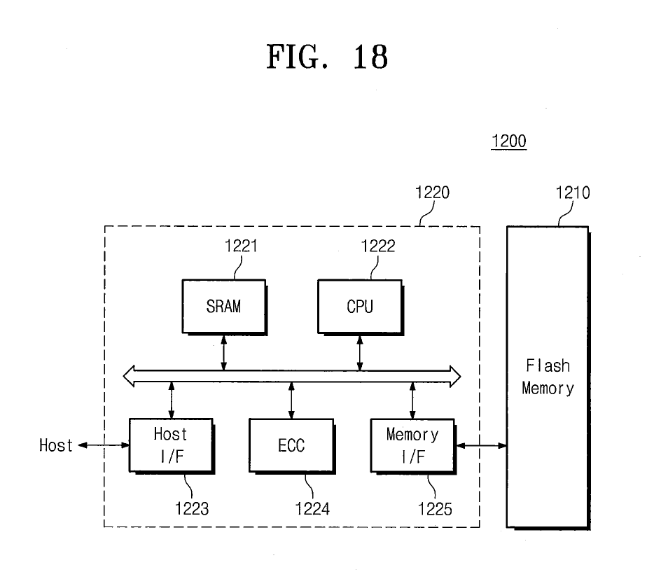

FIG. 18 is a schematic block diagram illustrating an example of a memory card including a semiconductor device according to some embodiments of present inventive concepts (e.g., as described herein with respect to FIGS. 1-16).

Referring to FIG. 18, a memory card 1200 according to some embodiments of present inventive concepts may include a memory device 1210. The memory device 1210 may include at least one of the semiconductor devices described herein with respect to FIGS. 1-16. The memory card 1200 may also include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as a working memory of the CPU 1222. Moreover, the memory controller 1220 may further include a host interface (I/F) unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data read out from the memory device 1210. The memory card 1200 may further include a read only memory (ROM) device that stores code data to interface with the host. The memory card 1200 may be used as a portable data storage card. Alternatively, the memory card 1200 may be realized as a solid state disk (SSD) used as a hard disk of a computer system.

According to some embodiments of present inventive concepts, a first oxide layer, a second oxide layer, and a third oxide layer may be sequentially formed on a bottom surface and a sidewall of a trench. The first oxide layer may have a uniform and relatively small thickness due to the third oxide layer. The first oxide layer may also be uniformly deposited in a narrow trench, and thus, it may be possible to impede/prevent a defect (e.g., a void or a seam) from being formed in the first oxide layer. Dangling bonds formed on the bottom surface and the sidewall of the trench may be removed during formation of the second oxide layer. The dangling bonds (i.e., interface traps) between an active region and the first oxide layer may be removed or reduced to improve the reliability of the semiconductor device. Due to the first oxide layer, the width of the active region may not be reduced during the formation of the second oxide layer.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

What is claimed is:

1. A method of fabricating a semiconductor device, the method comprising:
forming a trench in a substrate;
forming a first oxide layer in the trench;
forming a second oxide layer on the first oxide layer, wherein a first density of the second oxide layer is higher than a second density of the first oxide layer;
forming a third oxide layer on the second oxide layer; and
forming an insulating pattern on the third oxide layer such that the insulating pattern fills the trench.

2. The method of claim 1, wherein the third oxide layer is thicker than the first oxide layer, after forming the third oxide layer.

3. The method of claim 1, wherein the second oxide layer includes a same material as the first and third oxide layers.

4. The method of claim 1, wherein forming the second oxide layer comprises:
performing a thermal oxidation process to increase a density of an upper portion of the first oxide layer.

5. The method of claim 1, wherein a wet etch rate of the second oxide layer is lower than respective wet etch rates of the first and third oxide layers.

6. The method of claim 1, wherein forming the second oxide layer comprises:
removing a dangling bond between the substrate and the first oxide layer.

7. The method of claim 1,
wherein the trench comprises a first trench and a second trench,
wherein a first width of the first trench is different from a second width of the second trench, and
wherein a thickness of the first oxide layer on a bottom surface of the first trench is substantially equal to a thickness of the first oxide layer on a bottom surface of the second trench, after forming the third oxide layer.

8. The method of claim 1,
wherein forming the second oxide layer comprises forming the second oxide layer using a first temperature in a range of about 900° C. to about 1100° C., and
wherein forming the first oxide layer comprises forming the first oxide layer using a second temperature lower than the first temperature.

9. The method of claim 1, wherein forming the first oxide layer comprises conformally forming the first oxide layer on a bottom surface and a sidewall of the trench.

10. The method of claim 1, wherein the first oxide layer comprises a thickness in a range of about 30 Å to about 50 Å, after forming the third oxide layer.

11. The method of claim 1, further comprising:
planarizing the third oxide layer, the second oxide layer, and the first oxide layer to form a first oxide pattern, a second oxide pattern, and a third oxide pattern that are sequentially stacked, the first through third oxide patterns exposing at least a portion of the substrate outside of the trench;
forming a gate insulating pattern on the portion of the substrate exposed by the first through third oxide patterns; and
forming a gate electrode pattern on the gate insulating pattern.

12. A method of forming a semiconductor device, the method comprising:
forming a first oxide layer in first and second trenches of a substrate;
forming a second oxide layer on the first oxide layer in the first and second trenches; and
forming a third oxide layer on the second oxide layer in the first and second trenches,
wherein a thickness of the first oxide layer is substantially uniform in the first and second trenches, after forming the third oxide layer.

13. The method of claim 12, wherein, after forming the third oxide layer, the thickness of the first oxide layer comprises a first thickness that is thinner than a second thickness of the third oxide layer.

14. The method of claim 13,
wherein the first trench comprises a first width that is narrower than a second width of the second trench, and
wherein forming the first oxide layer comprises forming the first oxide layer in the second trench and in the first trench that comprises the first width that is narrower than the second width of the second trench.

15. The method of claim 13, wherein, after forming the third oxide layer, a ratio of the first thickness of the first oxide layer to the second thickness of the third oxide layer is about 1:4.

16. The method of claim 13, wherein, after forming the third oxide layer, the first thickness of the first oxide layer is in a range of about 30 Å to about 50 Å.

17. The method of claim 12, wherein forming the second oxide layer comprises performing a thermal oxidation process, after forming the first oxide layer, to increase a density of an upper portion of the first oxide layer.

18. A method of forming a semiconductor device, the method comprising:
forming a first oxide layer in first and second trenches of a substrate;
forming a second oxide layer on the first oxide layer in the first and second trenches; and
forming a third oxide layer on the second oxide layer in the first and second trenches, the first trench comprising a first width that is narrower than a second width of the second trench,
wherein a first thickness of the first oxide layer is substantially uniform in the first and second trenches, after forming the third oxide layer, and
wherein the first thickness of the first oxide layer is thinner than a second thickness of the third oxide layer, after forming the third oxide layer.

19. The method of claim 18, wherein, after forming the third oxide layer, the second thickness of the third oxide layer is thicker than a third thickness of the second oxide layer.

20. The method of claim 19, further comprising:
forming an insulating layer on the third oxide layer;
planarizing the insulating layer, the third oxide layer, the second oxide layer, and the first oxide layer until a surface of the substrate outside of the first and second trenches is exposed; and
forming a gate electrode pattern on the surface of the substrate after planarizing the insulating layer, the third oxide layer, the second oxide layer, and the first oxide layer.
